(19) United States
(12) Patent Application Publication
(10) Pub. No.: US 2025/0241181 A1
(43) Pub. Date: Jul. 24, 2025

(54) DISPLAY SUBSTRATE AND DISPLAY DEVICE

(71) Applicants: CHENGDU BOE OPTOELECTRONICS TECHNOLOGY CO., LTD., Chengdu (CN); BOE TECHNOLOGY GROUP CO., LTD., Beijing (CN)

(72) Inventors: Bingwei Yang, Beijing (CN); Hao Gao, Beijing (CN); Shun Wang, Beijing (CN); Yingqi Yuan, Beijing (CN); Shuang Zheng, Beijing (CN)

(21) Appl. No.: 18/703,291

(22) PCT Filed: Apr. 24, 2023
(86) PCT No.: PCT/CN2023/090331

§ 371 Date: Apr. 19, 2024

(51) Int. Cl. H10K 59/80; H10K 59/00; H10K 59/35

(52) U.S. Cl. CPC H10K 59/879; H10K 59/35; H10K 59/771; H10K 59/873

(57) ABSTRACT

A display substrate is provided, including: a base substrate and a first electrode, a first light-emitting layer, a first hole blocking layer, a first electron transport layer, an electron injection layer, a second electrode, an optical extraction layer, a protective layer, and an encapsulation layer that are sequentially arranged on the base substrate in a direction away from the base substrate. A refractive index of a material of the optical extraction layer is greater than a refractive index of a material of the encapsulation layer, and the refractive index of the material of the encapsulation layer is greater than a refractive index of a material of the second electrode.

### CROSS-REFERENCE TO RELATED APPLICATION

This application is a Section 371 National Stage Application of International Application No. PCT/CN2023/090331, filed Apr. 24, 2023, entitled “DISPLAY SUBSTRATE AND DISPLAY DEVICE”, which is incorporated herein by reference in its entirety.

### TECHNICAL FIELD

The present disclosure relates to the field of display technology, in particular, to a display substrate and a display device.

### BACKGROUND

Organic Light Emitting Diode (OLED) display devices have various pixel composition units, but full-color devices including units composed of RGB sub-pixels may be the current mainstream devices. For medium-sized OLED displays to large-sized OLED displays, when the uniformity monitoring is performed, scattered color shift positions (color shift margin) to some extent generally occur when viewing at a specific angle due to different positions, and the differences in color changes will directly affect the user's viewing experience.

The above information disclosed in this section is only for the purpose of understanding the background of the technical concept of the present disclosure. Therefore, the above information may include information that does not constitute the prior art.

### SUMMARY

To solve at least one aspect of the aforementioned problem, embodiments of the present disclosure provide a display substrate and a display device including the display substrate.

According to an aspect of the present disclosure, a display substrate is provided, including: a base substrate; a first electrode on the base substrate; a first light-emitting layer on a side of the first electrode away from the base substrate; a first hole blocking layer on a side of the first light-emitting layer away from the base substrate; a first electron transport layer on a side of the first hole blocking layer away from the base substrate; an electron injection layer on a side of the first electron transport layer away from the base substrate; a second electrode on a side of the electron injection layer away from the base substrate; an optical extraction layer on a side of the second electrode away from the base substrate; a protective layer on a side of the optical extraction layer away from the base substrate; and an encapsulation layer on a side of the protective layer away from the base substrate, the encapsulation layer including a plurality of layers. A refractive index of a material of the optical extraction layer is greater than a refractive index of a material of at least one layer in the encapsulation layer, and the refractive index of the material of the at least one layer in the encapsulation layer is greater than a refractive index of a material of the second electrode.

According to some exemplary embodiments, the display substrate includes a color shift adjustment layer, the color shift adjustment layer is selected from at least one of: the at least one layer in the encapsulation layer, the optical extraction layer, the protective layer or the second electrode, and the color shift adjustment layer and remaining film layers in the display substrate other than the color shift adjustment layer meet:

$${n}_{s} {L}_{s} + \sum {n}_{i} {L}_{i} / ( {n}_{1} + \sum {n}_{i} ) = T ,$$

where nₛ represents a refractive index of a material of the color shift adjustment layer, Lₛ represents a thickness of the color shift adjustment layer, nᵢ represents a refractive index of a material of one of the remaining film layers, and Lᵢ represents a thickness of the one of the remaining film layers; i is a positive integer, and T is in a range of 45 to 95.

According to some exemplary embodiments, the light-emitting layer includes an R sub-pixel, a G sub-pixel, and a B sub-pixel. The R sub-pixel is a first light-emitting sub-layer, the G sub-pixel is a second light-emitting sub-layer, and the B sub-pixel is a third light-emitting sub-layer.

According to some exemplary embodiments, the encapsulation layer includes: a first insertion layer on the side of the protective layer away from the base substrate; a first inorganic layer on a side of the first insertion layer away from the base substrate; an organic layer on a side of the first inorganic layer away from the base substrate; and a second inorganic layer on a side of the organic layer away from the base substrate.

According to some exemplary embodiments, a refractive index nₛ₁ of a material of the first insertion layer, a thickness Lₛ₁ of the first insertion layer, the refractive index nᵢ of the material of the one of the remaining film layers, and the thickness Lᵢ of the one of the remaining film layers meet:

$${n}_{s 1} {L}_{s 1} + \sum {n}_{i} {L}_{i} / ( {n}_{s 1} + \sum {n}_{i} ) = T ,$$

where T is in a range of 65 to 95.

According to some exemplary embodiments, a product nₛ₁·Lₛ₁ of the refractive index nₛ₁ of the material of the first insertion layer and the thickness Lₛ₁ of the first insertion layer is in a range of 70 to 230.

According to some exemplary embodiments, the refractive index nₛ₁ of the material of the first insertion layer is in a range of 1.5 to 1.7.

According to some exemplary embodiments, the refractive index nₛ₁ of the material of the first insertion layer and a refractive index n_{protective layer} of a material of the protective layer meet |nₛ₁-n_{protective layer}|>0.3.

According to some exemplary embodiments, a peak range of the first light-emitting sub-layer is 625 nm to 640 nm, a peak range of the second light-emitting sub-layer is 520 nm to 535 nm, and a peak range of the third light-emitting sub-layer is 455 nm to 465 nm.

According to some exemplary embodiments, the encapsulation layer includes: a first inorganic layer on the side of the protective layer away from the base substrate; an organic layer on a side of the first inorganic layer away from the base substrate; and a second inorganic layer on a side of the organic layer away from the base substrate.

According to some exemplary embodiments, a refractive index nₛ₂ of a material of the optical extraction layer, a thickness Lₛ₂ of the optical extraction layer, the refractive index nᵢ of the material of the one of the remaining film layers, and the thickness Lᵢ of the one of the remaining film layers meet:

$${n}_{s 2} {L}_{s 2} + \sum {n}_{i} {L}_{i} / ( {n}_{s 2} + \sum {n}_{i} ) = T ,$$

where T is in a range of 45 to 55.

According to some exemplary embodiments, a product nₛ₂·Lₛ₂ of the refractive index nₛ₂ of the material of the optical extraction layer and the thickness Lₛ₂ of the optical extraction layer is in a range of 90 to 150.

According to some exemplary embodiments, the refractive index nₛ₂ of the material of the optical extraction layer is in a range of 1.8 to 2.2.

According to some exemplary embodiments, the refractive index nₛ₂ of the material of the optical extraction layer and a refractive index n_{protective layer} of a material of the protective layer meet |nₛ₂-n_{protective layer}|>0.5.

According to some exemplary embodiments, a peak range of the first light-emitting sub-layer is 633 nm to 654 nm, a peak range of the second light-emitting sub-layer is 515 nm to 530 nm, and a peak range of the third light-emitting sub-layer is 455 nm to 465 nm.

According to some exemplary embodiments, a refractive index nₛ₃ of a material of the protective layer, a thickness Lₛ₃ of the protective layer, the refractive index nᵢ of the material of the one of the remaining film layers, and the thickness Lᵢ of the one of the remaining film layers meet:

$${n}_{s 3} {L}_{s 3} + \sum {n}_{i} {L}_{i} / ( {n}_{s 3} + \sum {n}_{i} ) = T ,$$

where T is in a range of 55 to 65.

According to some exemplary embodiments, a product nₛ₃·Lₛ₃ of the refractive index nₛ₃ of the material of the protective layer and the thickness Lₛ₃ of the protective layer is in a range of 50 to 110.

According to some exemplary embodiments, the refractive index nₛ₃ of the material of the protective layer is in a range of 1.3 to 1.5.

According to some exemplary embodiments, the refractive index nₛ₃ of the material of the protective layer and a refractive index n_{optical extraction layer} of the material of the optical extraction layer meet |nₛ₃-n_{optical extraction layer}|>0.5.

According to some exemplary embodiments, a peak range of the first light-emitting sub-layer is 615 nm to 630 nm, a peak range of the second light-emitting sub-layer is 515 nm to 530 nm, and a peak range of the third light-emitting sub-layer is 450 nm to 465 nm.

According to some exemplary embodiments, a refractive index nₛ₄ of a material of the second electrode, a thickness Lₛ₄ of the second electrode, the refractive index nᵢ of the material of the one of the remaining film layers, and the thickness Lᵢ of the one of the remaining film layers meet:

$${n}_{s 4} {L}_{s 4} + \sum {n}_{i} {L}_{i} / ( {n}_{s 4} + \sum {n}_{i} ) = T ,$$

where T is in a range of 60 to 65.

According to some exemplary embodiments, a product nₛ₄·Lₛ₄ of the refractive index nₛ₄ of the material of the second electrode and the thickness Lₛ₄ of the second electrode is in a range of 1.5 to 2.0.

According to some exemplary embodiments, the refractive index nₛ₄ of the material of the second electrode is in a range of 0.1 to 0.2.

According to some exemplary embodiments, the refractive index nₛ₄ of the material of the second electrode and a refractive index n_{optical extraction layer} of a material of the optical extraction layer meet |nₛ₄-n_{optical extraction layer}|>1.

According to some exemplary embodiments, a peak range of the first light-emitting sub-layer is 615 nm to 625 nm, a peak range of the second light-emitting sub-layer is 520 nm to 530 nm, and a peak range of the third light-emitting sub-layer is 455 nm to 465 nms.

According to some exemplary embodiments, the encapsulation layer includes: a first inorganic layer on the side of the protective layer away from the base substrate; a second insertion layer on a side of the first inorganic layer away from the base substrate; an organic layer on a side of the second insertion layer away from the base substrate; and a second inorganic layer on a side of the organic layer away from the base substrate.

According to some exemplary embodiments, a refractive index nₛ₅ of a material of the second insertion layer, a thickness Lₛ₅ of the second insertion layer, the refractive index nᵢ of the material of the one of the remaining film layers, and the thickness Lᵢ of the one of the remaining film layers meet:

$${n}_{s 5} {L}_{s 5} + \sum {n}_{i} {L}_{i} / ( {n}_{s 5} + \sum {n}_{i} ) = T ,$$

where T is in a range of 65 to 95.

According to some exemplary embodiments, a product nₛ₅·Lₛ₅ of the refractive index nₛ₅ of the material of the second insertion layer and the thickness Lₛ₅ of the second insertion layer is in a range of 80 to 160.

According to some exemplary embodiments, the refractive index nₛ₅ of the material of the second insertion layer is in a range of 1.5 to 1.7.

According to some exemplary embodiments, the refractive index nₛ₅ of the material of the second insertion layer and a refractive index n_{first inorganic layer} of a material of the first inorganic layer meet |nₛ₅-n_{first inorganic layer}|>0.15.

According to some exemplary embodiments, a peak range of the first light-emitting sub-layer is 620 nm to 635 nm, a peak range of the second light-emitting sub-layer is 515 nm to 530 nm, and a peak range of the third light-emitting sub-layer is 450 nm to 465 nms.

According to some exemplary embodiments, the above-mentioned display substrate may further include: a hole injection layer on the side of the first electrode away from the base substrate; a first hole transport layer on a side of the hole injection layer away from the base substrate; a second light-emitting layer on a side of the first hole transport layer away from the base substrate; a second hole blocking layer on a side of the second light-emitting layer away from the base substrate; a second electron transport layer on a side of the second hole blocking layer away from the base substrate; a charge generation layer on a side of the second electron transport layer away from the base substrate; and a second hole transport layer on a side of the charge generation layer away from the base substrate. The first light-emitting layer is on a side of the second hole transport layer away from the base substrate.

According to some exemplary embodiments, a material of the first electrode includes at least one of silver, indium tin oxide/silver/indium tin oxide, or a nickel chromium alloy. The material of the second electrode includes at least one of a transparent conductive oxide, a magnesium silver alloy, aluminum, magnesium, or silver.

According to some exemplary embodiments, Sdrop ≤0, and Sdrop is obtained through a following equation:

$$Sdrop = ( ( Ssplit - Sref . ) / Sref . ) * 100 \% ,$$

where Ssplit is an area of an enclosed color gamut of the display substrate in a color space, Sref. is an area of an enclosed color gamut of a reference display substrate in the color space, and Sdrop is a variation in split S with respect to Sref.

On another aspect, a display device is further provided, including the above-mentioned display substrate.

### BRIEF DESCRIPTION OF THE DRAWINGS

Through the following descriptions of the present disclosure with reference to the accompanying drawings, the other objectives and advantages of the present disclosure will be apparent, which may help to have a comprehensive understanding of the present disclosure.

FIG. 1A is a schematic diagram of a display substrate according to an embodiment of the present disclosure;

FIG. 1B is a schematic diagram of a stacked layer of a display substrate according to an embodiment of the present disclosure;

FIG. 1C is a schematic diagram of a display substrate including a plurality of first light-emitting layers according to an embodiment of the present disclosure;

FIG. 2 is a schematic diagram of an encapsulation layer according to an embodiment of the present disclosure;

FIG. 3A is a schematic diagram showing a linear relationship of Y-Sdrop in the prior art;

FIG. 3B is a schematic diagram showing a linear relationship of Y-Sdrop in a case of the encapsulation layer shown in FIG. 2 according to an embodiment of the present disclosure;

FIG. 3C is a diagram showing a trend of an effect of a thickness of a second electrode on a green light spectrum according to an embodiment of the present disclosure;

FIG. 4 is a schematic diagram of an encapsulation layer according to another embodiment of the present disclosure;

FIG. 5A is a schematic diagram showing a linear relationship of Y-Sdrop in a case of the encapsulation layer shown in FIG. 4 according to an embodiment of the present disclosure;

FIG. 5B is a diagram showing a trend of an effect of a thickness of a second electrode on a red light spectrum according to an embodiment of the present disclosure;

FIG. 6A is a schematic diagram showing a linear relationship of Y-Sdrop in a case where a protective layer is a color shift adjustment layer according to an embodiment of the present disclosure;

FIG. 6B is a diagram showing a trend of an effect of a thickness of a second electrode on a blue light spectrum according to an embodiment of the present disclosure;

FIG. 7A is a schematic diagram showing a linear relationship of Y-Sdrop in a case where a second electrode is a color shift adjustment layer according to an embodiment of the present disclosure;

FIG. 7B is a diagram showing a trend of an effect of a thickness of a second electrode on a blue light spectrum according to an embodiment of the present disclosure;

FIG. 8 is a schematic diagram of an encapsulation layer according to another embodiment of the present disclosure;

FIG. 9A is a schematic diagram showing a linear relationship of Y-Sdrop in a case of the encapsulation layer shown in FIG. 8 according to an embodiment of the present disclosure;

FIG. 9B is a diagram showing a trend of an effect of a thickness of a second electrode on a blue light spectrum according to an embodiment of the present disclosure.

It will be noted that for clarity, dimensions of layers, structures or regions may be enlarged or reduced in the drawings used to describe the embodiments of the present disclosure. That is, these drawings are not drawn to actual scales.

### DETAILED DESCRIPTION OF EMBODIMENTS

Hereinafter, further specific explanations of the technical solutions of the present disclosure will be provided through embodiments in conjunction with the accompanying drawings. In the specification, the same or similar reference numerals indicate the same or similar components. The following explanation of the embodiments of the present disclosure with reference to the accompanying drawings is intended to explain the overall inventive concept of the present disclosure and should not be understood as a limitation on the present disclosure.

In addition, in the following detailed description, for ease of explanation, many specific details are elaborated to provide a comprehensive understanding of the embodiments of the present disclosure. However, it is obvious that one or more embodiments may also be implemented without these specific details.

It will be understood that, although the terms “first”, “second”, etc. may be used here to describe different elements, these elements should not be limited by these terms. These terms are only used to distinguish one element from another. For example, without departing from the scope of exemplary embodiments, the first element may be named as the second element, and similarly, the second element may be named as the first element. The term “and/or” used here includes any combination and all combinations of one or more related listed items.

In will be understood that, when an element or a layer is referred to as “formed on” a further element or layer, the element or layer may be directly or indirectly formed on the further element or layer. That is to say, for example, there may be an intermediate element or an intermediate layer. On the contrary, when an element or a layer is referred to as “directly formed on” a further element or layer, there is no intermediate element or intermediate layer. Other expressions used to describe a relationship between elements or layers will be explained in a similar way (such as “between” and “directly between”, “adjacent” and “directly adjacent”, etc.).

Herein, unless otherwise specified, the expression “in the same layer” generally means that the first and second components may be formed using a same material and through a same patterning process. The expression “A and B are connected as an integral structure” indicates that the component A and the component B are formed as an integral structure, that is, they usually include a same material and are formed as a continuous component as a whole in structure.

Herein, unless otherwise specified, oriental terms such as “up”, “down”, “left”, “right”, “inside”, “outside” are used to represent an orientation or a positional relationship based on the drawings, and they are only for ease of description of the present disclosure, but are not to indicate or imply that the device, element or component referred has to have a specific orientation, or be constructed or operated in a specific orientation. It will be understood that when an absolute position of a described object changes, a relative positional relationship they represent may also change accordingly. Therefore, these directional terms should not be understood as a limitation on the present disclosure.

Herein, the expression “vertical”, “vertical connection” or similar expressions not only include a case of 90 degrees, namely a case of being completely vertical, but also include a case of a deviation from 90 degrees within a certain error range, for example, a case of a deviation from 90 degrees within a fabrication error range.

Those skilled in the art will understand that herein, unless otherwise specified, the expression “height” or “thickness” refers to a dimension along a surface of each film layer provided perpendicular to the display substrate, that is, a dimension along a light output direction of the display substrate, or a dimension along a normal direction of the display device.

Herein, oriental expressions such as “first direction” and “second direction” are used to describe different directions along pixel units, such as vertical and horizontal directions of pixel units, or row and column directions of sub-pixel arrangements. It will be understood that these representations are only illustrative, but not limitations on the present disclosure.

Full color devices including units composed of RGB sub-pixels may be regarded as the current mainstream devices. The monochromatic properties of RGB sub-pixels have different effects on the synthesized white light, and this may lead to angular color differences. Therefore, reducing the sensitivity of white light to monochromatic light as the angle changes is the key to adjusting the color shift of the white light. For medium-sized OLED displays and large-sized OLED displays, when the uniformity monitoring is performed, scattered color shift positions (color shift margin) to some extent occur when viewing at a specific angle due to different positions, and the differences in color changes will directly affect the user's viewing experience. At present, the solution to the problem of color shift margin is generally to control the monochromatic CIE, that is, controlling the distribution of color shift by controlling the actual CIE range. However, this method directly limits the capacity of the device and a degree of the process fluctuation, leading to a sharp increase in the production difficulty.

A color shift change of white light of an OLED device is generally affected by a change pattern of RGB light. In view of this, in the embodiments of the present disclosure, a degree of an effect of RGB light on the color shift of the white light is adjusted, so as to adjust the angular margin of the white light. In this way, the color shift difference at different points of the product may be reduced.

Specifically, the embodiments of the present disclosure provide a display substrate, including: a base substrate; a first electrode on the base substrate; a first light-emitting layer on a side of the first electrode away from the base substrate; a first hole blocking layer on a side of the first light-emitting layer away from the base substrate; a first electron transport layer on a side of the first hole blocking layer away from the base substrate; an electron injection layer on a side of the first electron transport layer away from the base substrate; a second electrode on a side of the electron injection layer away from the base substrate; an optical extraction layer on a side of the second electrode away from the base substrate; a protective layer on a side of the optical extraction layer away from the base substrate; and an encapsulation layer on a side of the protective layer away from the base substrate. The encapsulation layer includes a plurality layers. A refractive index of a material of the optical extraction layer is greater than a refractive index of a material of at least one layer of the encapsulation layer, and the refractive index of the material of the at least one layer of the encapsulation layer is greater than a refractive index of a material of the second electrode.

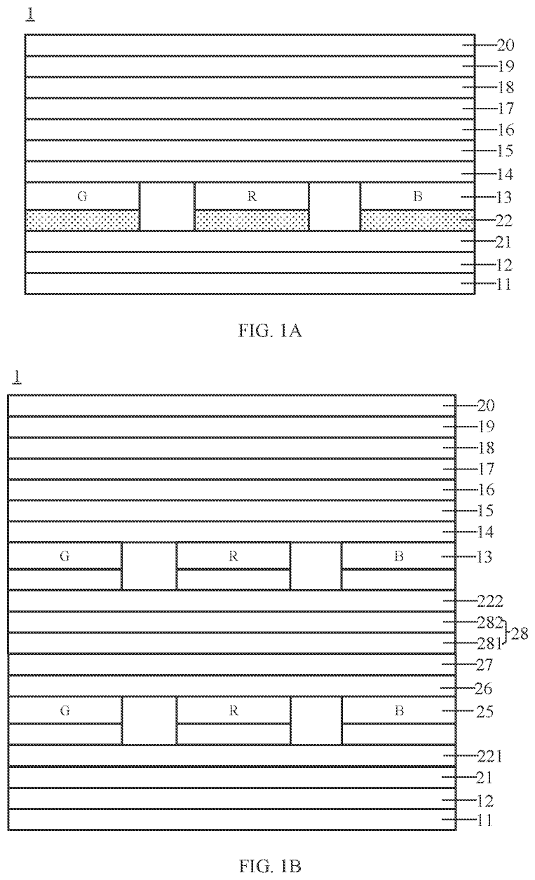

FIG. 1A is a schematic diagram of a display substrate according to an embodiment of the present disclosure.

As shown in FIG. 1A, the display substrate 1 may include: a base substrate 11; a first electrode 12 on the base substrate 11; a first light-emitting layer 13 on a side of the first electrode 12 away from the base substrate 11; a first hole blocking layer 14 on a side of the first light-emitting layer 13 away from the base substrate 11; a first electron transport layer 15 on a side of the first hole blocking layer 14 away from the base substrate 11; an electron injection layer 16 on a side of the first electron transport layer 15 away from the base substrate 11; a second electrode 17 on a side of the electron injection layer 16 away from the base substrate 11; an optical extraction layer 18 on a side of the second electrode 17 away from the base substrate 11; a protective layer 19 on a side of the optical extraction layer 18 away from the base substrate 11; and an encapsulation layer 20 on a side of the protective layer 19 away from the base substrate. The encapsulation layer includes a plurality of layers, a refractive index of a material of the optical extraction layer 18 is greater than a refractive index of a material of at least one layer of the encapsulation layer 20, and the refractive index of the material of the at least one layer of the encapsulation layer 20 is greater than a refractive index of a material of the second electrode 17.

According to an embodiment of the present disclosure, the first electrode 12 may serve as an anode, and the second electrode 17 may serve as a cathode. The display substrate provided in the embodiments of the present disclosure may be a top emission device. Therefore, anode and cathode materials of the top emission OLED device in the prior art may be used, and the anode and cathode materials in the embodiments of the present disclosure may be adjusted according to actual needs. For example, a material of the first electrode may include at least one of silver (Ag), indium tin oxide/silver/indium tin oxide (ITO/Ag/ITO), or a nickel chromium alloy (Ni:Cr alloy). A material of the second electrode 17 may be at least one selected from a transparent conductive oxide, a magnesium silver alloy, aluminum, magnesium, or silver, for example, ITO and other transparent conductive oxides, and Mg/Ag/Al/or alloys may be preferred.

According to an embodiment of the present disclosure, the first light-emitting layer 13 may include structures of R, G, and B sub-pixels, where the R sub-pixel may serve as a first sub light-emitting layer, the G sub-pixel may serve as a second sub light-emitting layer, and the B sub-pixel may serve as a third sub light-emitting layer.

According to an embodiment of the present disclosure, the color shift reduction solution in the present disclosure may be applied to top emission devices, as there may be a structure enhancing microcavity refraction in the top emission device, thereby reducing the color shift phenomenon of the display substrate.

According to an embodiment of the present disclosure, the encapsulation layer may include at least one of a first insertion layer, a first inorganic layer, a second insertion layer, an organic layer or a second inorganic layer. The color shift phenomenon of the display substrate may be reduced by performing color shift adjustment on one or more layers in the second electrode 17, the optical extraction layer 18, the protective layer 19, and the encapsulation layer 20.

According to an embodiment of the present disclosure, a hole injection layer 21, a hole transport layer 22, etc. may be provided between the first electrode 12 and the first light-emitting layer 13 as desired, which will not be repeated here.

FIG. 1B is a schematic diagram of a stack of a display substrate according to an embodiment of the present disclosure.

As shown in FIG. 1B, the display substrate 1 may further include: the hole injection layer 21 on the side of the first electrode 12 away from the base substrate 11; a first hole transport layer 221 on a side of the hole injection layer 21 away from the base substrate 11; a second light-emitting layer 25 on a side of the first hole transport layer 221 away from the base substrate 11; a second hole blocking layer 26 on a side of the second light-emitting layer 25 away from the base substrate 11; a second electron transport layer 27 on a side of the second hole blocking layer 26 away from the base substrate 11; a charge generation layer 28 on a side of the second electron transport layer 27 away from the base substrate 11; and a second hole transport layer 222 on a side of the charge generation layer 28 away from the base substrate 11, where the first light-emitting layer 13 is on a side of the second hole transport layer 222 away from the base substrate 11. The charge generation layer 28 may include an N-type charge generation layer 281 and a P-type charge generation layer 282. It will be understood that the color shift reduction solution provided in the embodiments of the present disclosure may also be applied to the stack device shown in FIG. 1B.

FIG. 1C is a schematic diagram of a display substrate including a plurality of first light-emitting layers according to an embodiment of the present disclosure.

The first light-emitting layer 13 in the display substrate 1 may be provided with one layer or a plurality of layers, as shown in FIG. 1C. The main difference between FIG. 1C and FIG. 1A is that two first light-emitting layers 13 are provided in FIG. 1C, as well as that an electron generation layer 23, a hole generation layer 24, a hole transport layer 22, etc. are provided between the two first light-emitting layers. Optionally, three first light-emitting layers sequentially stacked may be provided in the display substrate, and correspondingly, structures such as the electron generation layer, the hole generation layer and the hole transport layer may be provided between the light-emitting layers according to actual needs, which will not be repeated here. It may be understood that the color shift reduction solution provided in the embodiments of the present disclosure may be applied to a display substrate having a single first light-emitting layer structure, as well as to a display substrate having a plurality of first light-emitting layers that are stacked.

According to the embodiments of the present disclosure, at least one of the encapsulation layer 20, the optical extraction layer 18, the protective layer 19 or the second electrode 17 may serve as the color shift adjustment layer to reduce the color shift phenomenon of the display substrate. The color shift adjustment layer and the remaining film layers in the display substrate other than the color shift adjustment layer may have a relationship represented by equation (1):

$${n}_{s} {L}_{s} + \sum {n}_{i} {L}_{i} / ( {n}_{1} + \sum {n}_{i} ) = T . \qquad ( 1 )$$

Here, nₛ represents a refractive index of a material of the color shift adjustment layer, Lₛ represents a thickness of the color shift adjustment layer, nᵢ represents a refractive index of a material of one of the remaining film layers, Lᵢ represents a thickness of the one of the remaining film layers, i is a positive integer, and T is in a range of 45 to 95.

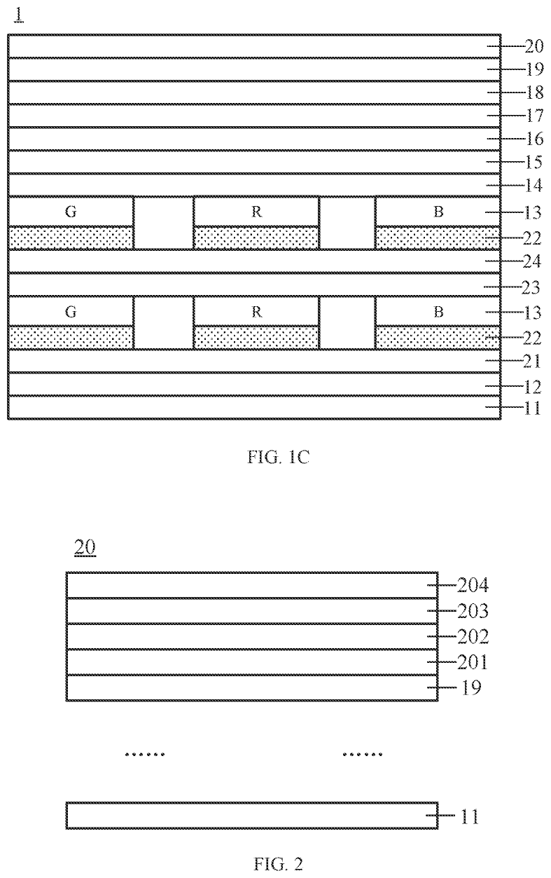

FIG. 2 is a schematic diagram of an encapsulation layer according to an embodiment of the present disclosure.

As shown in FIG. 2, the encapsulation layer 20 may include: a first insertion layer 201 on the side of the protective layer 19 away from the base substrate 11; a first inorganic layer 202 on a side of the first insertion layer 201 away from the base substrate 11; an organic layer 203 on a side of the first inorganic layer 202 away from the base substrate 11; and a second inorganic layer 204 on a side of the organic layer 203 away from the base substrate. The sign “ . . . ” in FIG. 2 may represent an omitted film layer structure between the base substrate 11 and the protective layer 19.

According to an embodiment of the present disclosure, in the case where the encapsulation layer 20 includes the first insertion layer 201, the first inorganic layer 202, the organic layer 203 and the second inorganic layer 204, the first insertion layer 201 may solely serve as the color shift adjustment layer to reduce the color shift phenomenon of the display substrate. A refractive index nₛ₁ of a material of the first insertion layer 201, a thickness Lₛ₁ of the first insertion layer 201, the refractive index nᵢ of the material of the one of the remaining film layers, and the thickness Lᵢ of the one of the remaining film layers may have a relationship represented by equation (2):

$${n}_{s 1} {L}_{s 1} + \sum {n}_{i} {L}_{i} / ( {n}_{s 1} + \sum {n}_{i} ) = T . \qquad ( 2 )$$

Here, T is in a range of 65 to 95; a product nₛ₁·Lₛ₁ of the refractive index nₛ₁ of the material of the first insertion layer 201 and the thickness Lₛ₁ of the first insertion layer 201 is in a range of 70 to 230; the refractive index nₛ₁ of the material of the first insertion layer 201 is in a range of 1.4 to 1.7, preferred in a range of 1.5 to 1.7; and the refractive index nₛ₁ of the material of the first insertion layer 201 and a refractive index n_{protective layer} of the material of the protective layer 19 meet |nₛ₁-n_{protective layer}|>0.3.

In an embodiment of the present disclosure, in order to verify the display substrate obtained through the above parameters, Sdrop is used to measure the variation in color shift margin with respect to reference data ref. Specifically, Sdrop may be determined using equation (3):

$$Sdrop = ( ( Ssplit - Sref . ) / Sref . ) * 100 \% . \qquad ( 3 )$$

Here, Ssplit is obtained during a testing process of the above display substrate, which is an area (scatter distribution area) of an enclosed color gamut in the color space. Sref. is the reference data for the display substrate under the same testing conditions, which may be understood as an area of an enclosed color gamut of a reference display substrate in the color space. Sdrop is a variation in Ssplit with respect to Sref. Ref. Sdrop=0% is the minimum standard, and Sdrop being a negative value may indicate the color shift is reduced.

Further, the embodiments of the present disclose further proposes a calculation scheme for balancing the RGB monochromatic effects. In this calculation scheme, a monochromatic effect factor Y is introduced, and a sensitivity factor is defined according to a slope of a linear relationship between Y and Sdrop. Reducing the sensitivity factor may reduce the white light angular margin. Y may be determined by equation (4):

$$Y = {A [ \sum {Ki ( {CIE}_{max} - {CIE}_{min} )}^{2} ]}^{\frac{1}{2}} = {A [ K 1 {( Rx\_max - Rx\_min )}^{2} + K {1}^{′} {( Ry\_max - Ry\_min )}^{2} + K 2 {( Gx\_max - Gx\_min )}^{2} + K {2}^{′} {( Gy\_max - Gy\_min )}^{2} + K 3 {( Bx\_max - Bx\_min )}^{2} + K {3}^{′} {( By\_max - By\_min )}^{2} ]}^{1 / 2} . \qquad ( 4 )$$

Here, CIE_max and CIE_min are respectively the maximum and minimum values of a range of monochromatic CIE (the color space defined mathematically) obtained from sample testing; R represents red, G represents green, and B represents blue; x and y may respectively represent the x and y coordinate values in the color coordinates, and K1 to K3′ may represent weight coefficients of monochromatic CIE on the white light (ΣK1=2.5). Specifically, K1 may be in a range of 0.2 to 0.4, K2 may be in a range of 0.3 to 0.6, K3 may be in a range of 0.06 to 0.09, K1′ may be in a range of 0.1 to 0.15, K2′ may be in a range of 0.5 to 0.7, and KY may be in a range of 0.7 to 0.9. A is a proportional coefficient.

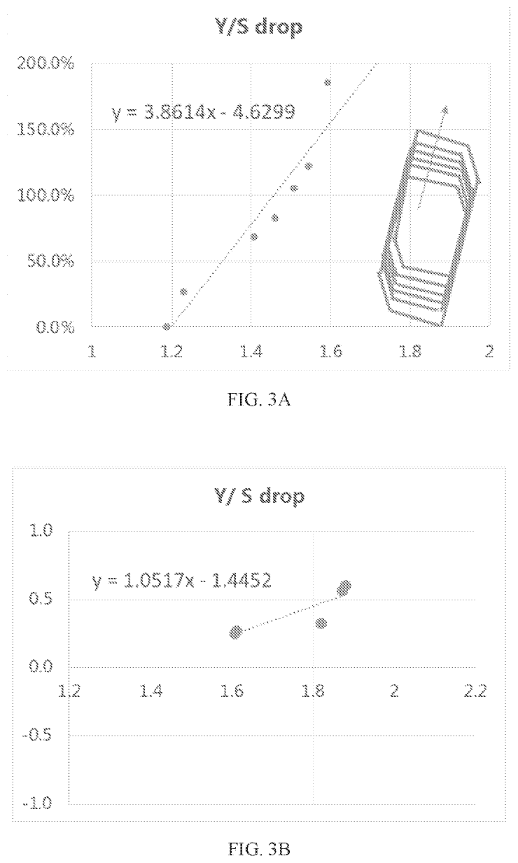

FIG. 3A is a schematic diagram showing a linear relationship of Y-Sdrop in the prior art.

As shown in FIG. 3A, the vertical and horizontal coordinates may be the monochromatic effect factor Y and Sdrop, respectively. Borders in FIG. 3A may represent a trend of change in the area. The main variable causing the difference in Y values is the variation in the microcavity length. The slope of the linear relationship is defined as the sensitivity factor. The relationship between the impact of monochromatic variation and the sensitivity factor of white light may be substantially as follows: the sensitivity factor being smaller than 1 indicates that the effect of monochromatic variation on the white light is small; the sensitivity factor being equal to 1 indicates that the monochromatic variation and the white light are equivalent; the sensitivity factor being greater than 1 indicates that the white light is significantly affected by the monochromaticity. The sensitivity factor in the prior art is 3.861 in FIG. 3A. By improving the device structure in the prior art, the reduction of the white light angular margin may be achieved.

FIG. 3B is a schematic diagram showing a linear relationship of Y-Sdrop in a case of the encapsulation layer shown in FIG. 2 according to an embodiment of the present disclosure.

As shown in FIG. 3B, in the case where the encapsulation layer 20 includes the first insertion layer 201, the first inorganic layer 202, the organic layer 203 and the second inorganic layer 204, and the first insertion layer 201 may solely serve as the color shift adjustment layer, by using the above parameter settings, the effect of a microcavity length variation on Sdrop, i.e. the sensitivity factor of Y-Sdrop, may be 1.05. 1.05 is less than 3.861 in the prior art, indicating that the display device provided in the embodiments of the present disclosure may effectively reduce the color shift.

Further, a peak of the emitted light is detected in the embodiments of the present disclosure. In the case where the first insertion layer 201 serves as the color shift adjustment layer, a peak position of a spectrum of the first light-emitting sub-layer may be in a range of 625 nm to 640 nm, a peak position of a spectrum of the second light-emitting sub-layer may be in a range of 520 nm to 535 nm, and a peak position of a spectrum of the third light-emitting sub-layer may be in a range of 455 nm to 465 nm.

FIG. 3C is a diagram showing a trend of an effect of a thickness of a second electrode on a green light spectrum according to an embodiment of the present disclosure.

In the embodiments of the present disclosure, only the relationship between the thickness of the film layer and the refractive index of the film layer may be defined. When the material of the second electrode 17 is preferably Mg/Ag/Al or an alloy, the trend of the effect of the thickness of the second electrode 17 on the RGB light spectrums is as follows. When the thickness of the second electrode 17 is in a range of 8 nm to 16 nm, R_Peak_wave is in a range of 625 nm to 635 nm; B_Peak_wave is in a range of 445 nm to 465 nm; and G_Peak_wave conforms to the segmentation pattern shown in FIG. 3B. In FIG. 3B, the horizontal coordinate may represent the thickness of the second electrode 17, and the vertical coordinate may represent a variation range of the peak position in the green light spectrum. When the thickness of the second electrode 17 is in a range of 12 nm to 14 nm, the peak position in the green light spectrum may show a sudden increasing trend. Here, R_Peak_wave may represent the peak position of the red light spectrum, G_Peak_wave may represent the peak position of the green light spectrum, and B_Peak_wave may represent the peak position of the blue light spectrum.

According to the embodiments of the present disclosure, a film layer structure between the first hole blocking layer 14 and the encapsulation layer 20 may form a microcavity. By matching the relationship between the thickness of the color shift adjustment layer with the refractive index and then defining the relationship, the microcavity effect may be adjusted to reduce the slope of Y-Sdrop linear relationship, so as to reduce the sensitivity factor. In this way, the color shift phenomenon of the display substrate may be reduced.

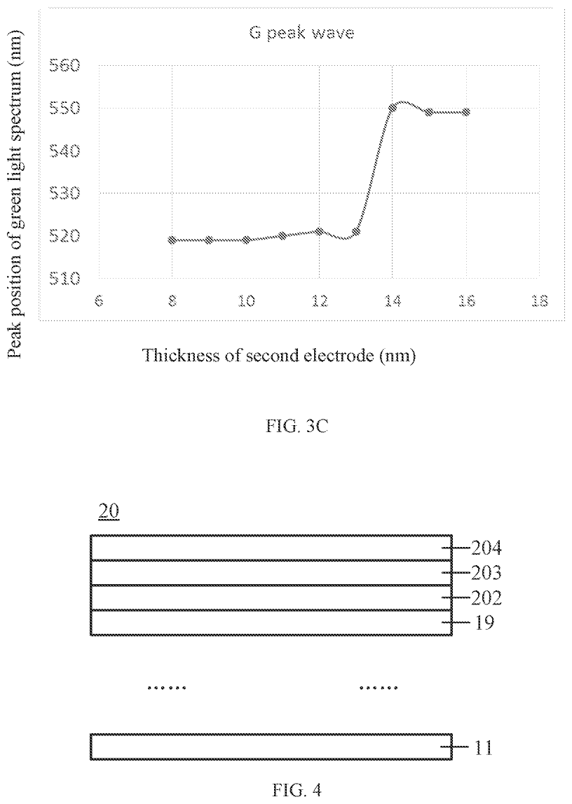

FIG. 4 is a schematic diagram of an encapsulation layer according to another embodiment of the present disclosure.

As shown in FIG. 4, the encapsulation layer 20 may include: a first inorganic layer 202 on the side of the protective layer 19 away from the base substrate 11; an organic layer 203 on a side of the first inorganic layer 202 away from the base substrate 11; and a second inorganic layer 204 on a side of the organic layer 203 away from the base substrate. The sign “ . . . ” in FIG. 4 may represent an omitted film layer structure between the substrate 11 and the protective layer 19.

According to an embodiment of the present disclosure, in the case where the encapsulation layer 20 includes the first inorganic layer 202, the organic layer 203 and the second inorganic layer 204, the optical extraction layer 18 may solely serve as the color shift adjustment layer to reduce the color shift phenomenon of the display substrate. Specifically, a refractive index nₛ₂ of a material of the optical extraction layer 18, a thickness Lₛ₂ of the optical extraction layer 18, a refractive index nᵢ of a material of one of the remaining film layers and the thickness Lᵢ of the one of the remaining film layer may have a relationship represented by equation (5):

$${n}_{s 2} {L}_{s 2} + \sum {n}_{i} {L}_{i} / ( {n}_{s 2} + \sum {n}_{i} ) = T . \qquad ( 5 )$$

Here, T is in a range of 45 to 55. A product nₛ₂·Lₛ₂ of the refractive index nₛ₂ of the material of the optical extraction layer and the thickness Lₛ₂ of the optical extraction layer is in a range of 90 to 150; the refractive index nₛ₂ of the material of the optical extraction layer is in a range of 1.8 to 2.2; and the refractive index nₛ₂ of the material of the optical extraction layer 18 and a refractive index n_{protective layer} of the material of the protective layer meet |nₛ₂-n_{protective layer}|>0.5.

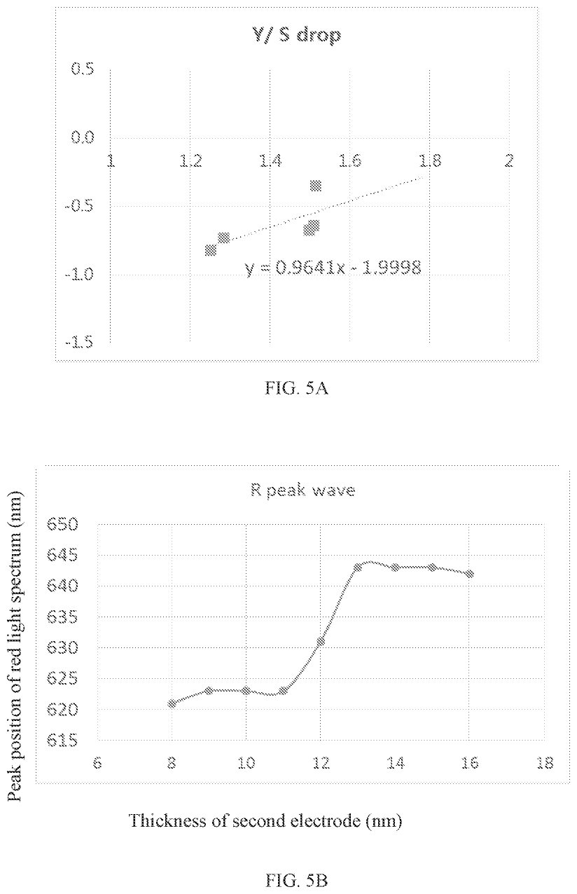

FIG. 5A is a schematic diagram showing a linear relationship of Y-Sdrop in a case of the encapsulation layer shown in FIG. 4 according to an embodiment of the present disclosure.

As shown in FIG. 5A, in the case where the encapsulation layer 20 includes the first inorganic layer 202, the organic layer 203 and the second inorganic layer 204, and the optical extraction layer 18 may solely serve as the color shift adjustment layer, by using the above parameter settings, the effect of the microcavity length variation on Sdrop, i.e. the sensitivity factor of Y-Sdrop, may be 0.96. The effects of RGB monochromatic fluctuations on the white light under the display substrate structure in this embodiment decreases significantly. 0.96 is less than 3.861 in the prior art, indicating that the display device provided in the embodiments of the present disclosure may effectively reduce the color shift.

Further, the peak of the emitted light is detected in the embodiments of the present disclosure. In the case where the optical extraction layer 18 serves as the color shift adjustment layer, the peak position of the spectrum of the first light-emitting sub-layer may be in a range of 633 nm to 654 nm, the peak position of the spectrum of the second light-emitting sub-layer may be in a range of 515 nm to 530 nm, and the peak position of the spectrum of the third light-emitting sub-layer may be in a range of 455 nm to 465 nm.

FIG. 5B is a diagram showing a trend of an effect of a thickness of a second electrode on a red light spectrum according to an embodiment of the present disclosure.

In the embodiments of the present disclosure, only the relationship between the thickness of the film layer and the refractive index of the film layer may be defined. When the material of the second electrode 17 is preferably Mg/Ag/Al or an alloy, the trend of the effect of the thickness of the second electrode 17 on the RGB light spectrums is as follows. When the thickness of the second electrode 17 is in a range of 8 nm to 16 nm, G_Peak_wave is in a range of 515 nm to 525 nm; B_Peak_wave is in a range of 450 nm to 465 nm; and R_Peak_wave conforms to the segmentation pattern shown in FIG. 5B. In FIG. 5B, the horizontal coordinate may represent the thickness of the second electrode 17, and the vertical coordinate may represent a variation range of the peak position in the red light spectrum. When the thickness of the second electrode 17 is in a range of 10 nm to 14 nm, the peak position of the red light spectrum may show a sudden increasing trend. Here, R_Peak_wave may represent the peak position in the red light spectrum, G_Peak_wave may represent the peak position of the green light spectrum, and B_Peak_wave may represent the peak position of the blue light spectrum.

According to an embodiment of the present disclosure, in the case where the encapsulation layer 20 includes the first inorganic layer 202, the organic layer 203 and the second inorganic layer 204, the protective layer 19 may solely serve as the color shift adjustment layer to reduce the color shift phenomenon of the display substrate. Specifically, a refractive index nₛ₃ of a material of the protective layer 19, a thickness Lₛ₃ of the protective layer 19, the refractive index nᵢ of a material of one of the remaining film layers, and the thickness Lᵢ of the one of the remaining film layers may have a relationship represented by equation (6):

$${n}_{s 3} {L}_{s 3} + \sum {n}_{i} {L}_{i} / ( {n}_{s 3} + \sum {n}_{i} ) = T . \qquad ( 6 )$$

Here, T is in a range of 55 to 65. A product nₛ₃·Lₛ₃ of the refractive index nₛ₃ of the material of the protective layer 19 and the thickness Lₛ₃ of the protective layer 19 is in a range of 50 to 110; the refractive index nₛ₃ of the material of the protective layer 19 is in a range of 1.3 to 1.5; the refractive index nₛ₃ of the material of the protective layer 19 and a refractive index n_{optical extraction layer} of the material of the optical extraction layer meet |nₛ₃-n_{optical extraction layer}|>0.5.

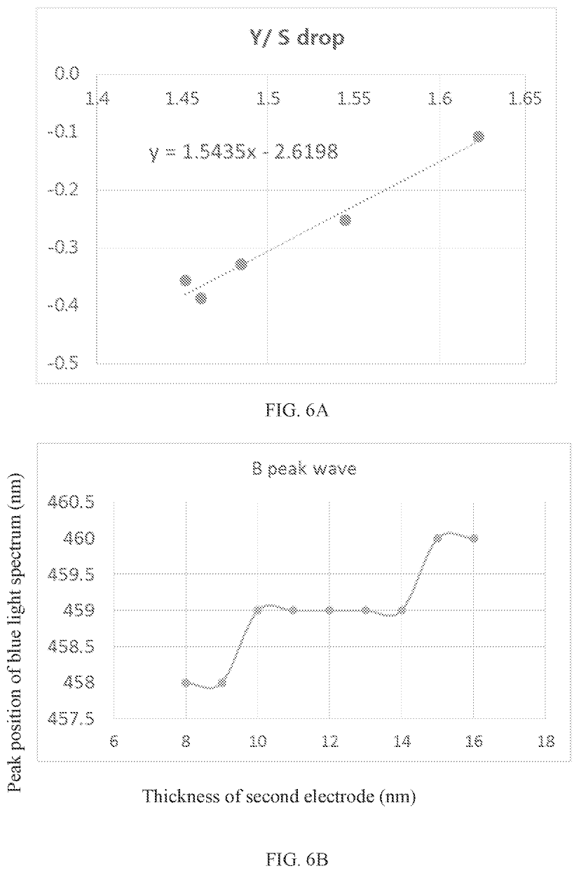

FIG. 6A is a schematic diagram showing a linear relationship of Y-Sdrop in a case where a protective layer is a color shift adjustment layer according to an embodiment of the present disclosure.

As shown in FIG. 6A, in the case where the encapsulation layer 20 includes the first inorganic layer 202, the organic layer 203 and the second inorganic layer 204, and the protective layer 19 may solely serve as the color shift adjustment layer, by using the above parameter settings, the effect of the microcavity length variation on Sdrop, i.e. the sensitivity factor of Y-Sdrop, may be 1.54. 1.54 is less than 3.861 in the prior art, indicating that the display device provided in the embodiments of the present disclosure may effectively reduce the color shift.

Further, the peak of the emitted light is detected in the embodiments of the present disclosure. In the case where the protective layer 19 serves as the color shift adjustment layer, the peak position of the spectrum of the first light-emitting sub-layer may be in a range of 615 nm to 630 nm, the peak position of the spectrum of the second light-emitting sub-layer may be in a range of 515 nm to 530 nm, and the peak position of the spectrum of the third light-emitting sub-layer may be in a range of 450 nm to 465 nm.

FIG. 6B is a diagram showing a trend of an effect of a thickness of a second electrode on a blue light spectrum according to an embodiment of the present disclosure.

In the embodiments of the present disclosure, only the relationship between the thickness of the film layer and the refractive index of the film layer may be defined. When the material of the second electrode 17 is preferably Mg/Ag/Al or an alloy, the trend of the effect of the thickness of the second electrode 17 on the RGB light spectrums is as follows. When the thickness of the second electrode 17 is in a range of 8 nm to 16 nm, R_Peak_wave=1.7 L+603 (L may represent the thickness of the second electrode); G_Peak_wave=0.58x+516 (x may represent the thickness of the second electrode); and B_Peak_wave conforms to the segmentation pattern shown in FIG. 6B. In FIG. 6B, the horizontal coordinate may represent the thickness of the second electrode 17, and the vertical coordinate may represent the variation range of the peak position of the blue light spectrum. When the thickness of the second electrode 17 is in a range of 8 nm to 10 nm and a range of 14 nm to 16 nm, the peak position of the blue light spectrum may show a sudden increasing trend. Here, R_Peak_wave may represent the peak position of the red light spectrum, G_Peak_wave may represent the peak position of the green light spectrum, and B_Peak_wave may represent the peak position of the blue light spectrum.

According to an embodiment of the present disclosure, in the case where the encapsulation layer 20 includes the first inorganic layer 202, the organic layer 203 and the second inorganic layer 204, the second electrode 17 may solely serve as the color shift adjustment layer to reduce the color shift phenomenon of the display substrate. Specifically, a refractive index nₛ₄ of a material of the second electrode 17, a thickness Lₛ₄ of the second electrode 17, the refractive index nᵢ of a material of one of the remaining film layers, and the thickness Lᵢ of the one of the remaining film layers may have a relationship represented by equation (7):

$${n}_{s 4} {L}_{s 4} + \sum {n}_{i} {L}_{i} / ( {n}_{s 4} + \sum {n}_{i} ) = T . \qquad ( 7 )$$

Here, T is in a range of 60 to 65. A product nₛ₄·Lₛ₄ of the refractive index nₛ₄ of the material of the second electrode 17 and the thickness Lₛ₄ of the second electrode 17 is in a range of 1.5 to 2.0; the refractive index nₛ₄ of the material of the second electrode 17 is in a range of 0.1 to 0.2; the refractive index nₛ₄ of the material of the second electrode 17 and the refractive index n_{optical extraction layer} of the material of the optical extraction layer 18 meet |nₛ₄-n_{optical extraction layer}|>1.

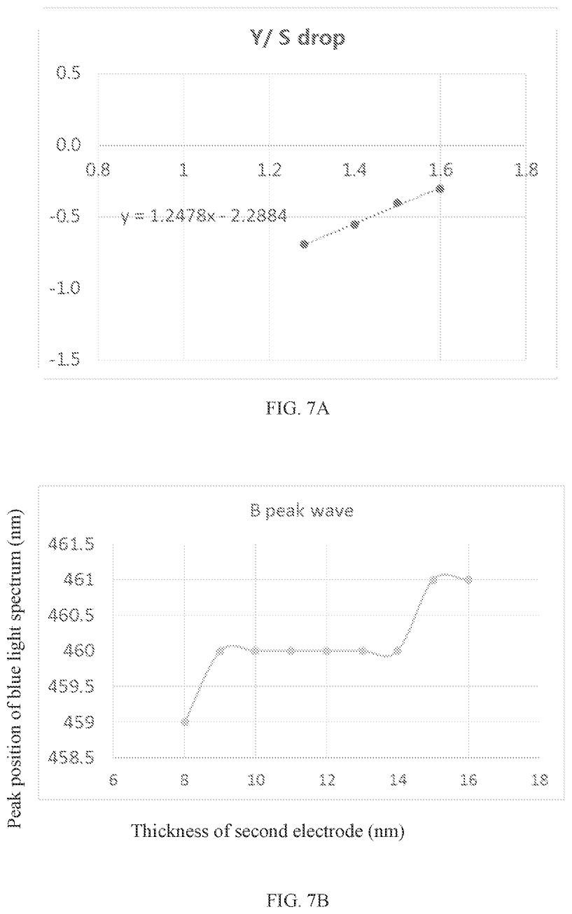

FIG. 7A is a schematic diagram showing a linear relationship of Y-Sdrop in a case where a second electrode is a color shift adjustment layer according to an embodiment of the present disclosure.

As shown in FIG. 7A, in the case where the encapsulation layer 20 includes the first inorganic layer 202, the organic layer 203 and the second inorganic layer 204, and the protective layer 19 may solely serve as the color shift adjustment layer, by using the above parameter settings, the effect of microcavity length variation on Sdrop, i.e. the sensitivity factor of Y-Sdrop, may be 1.25. An intensity of RGB microcavity is sensitive to the cathode, and change of the cathode configuration may have a significant effect on the adjustment of the color shift sensitivity of the white light. 1.25 is less than 3.861 in the prior art, and the present disclosure shows significant improvement compared to the prior art, indicating that the display device provided in the embodiments of the present disclosure may effectively reduce the color shift.

Further, the peak of the emitted light is detected in the embodiments of the present disclosure. In the case where the second electrode 17 serves as the color shift adjustment layer, the peak position of the spectrum of the first light-emitting sub-layer may be in a range of 615 nm to 625 nm, the peak position of the spectrum of the second light-emitting sub-layer may be in a range of 520 nm to 530 nm, and the peak position of the spectrum of the third light-emitting sub-layer may be in a range of 455 nm to 465 nm.

FIG. 7B is a diagram showing a trend of an effect of a thickness of a second electrode on a blue light spectrum according to an embodiment of the present disclosure.

In the embodiments of the present disclosure, only the relationship between the thickness of the film layer and the refractive index of the film layer may be defined. When the material of the second electrode 17 is preferably Mg/Ag/Al or an alloy, the trend of the effect of the thickness of the second electrode 17 on the RGB light spectrums is as follows. When the thickness of the second electrode 17 is in a range of 8 nm to 16 nm, R_Peak_wave=0.8 L+610 (L may represent the thickness of the second electrode); G_Peak_wave=0.7167 L+516 (L may represent the thickness of the second electrode); and B_Peak_wave conforms to the segmentation pattern shown in FIG. 7B. In FIG. 7B, the horizontal coordinate may represent the thickness of the second electrode 17, and the vertical coordinate may represent the variation range of the peak position of the blue light spectrum. When the thickness of the second electrode 17 is in a range of 8 nm to 10 nm and a range of 14 nm to 16 nm, the peak position of the blue light spectrum may show a sudden increasing trend. R_Peak_wave may represent the peak position in the red light spectrum, G_Peak_wave may represent the peak position of the green light spectrum, and B_Peak_wave may represent the peak position of the blue light spectrum.

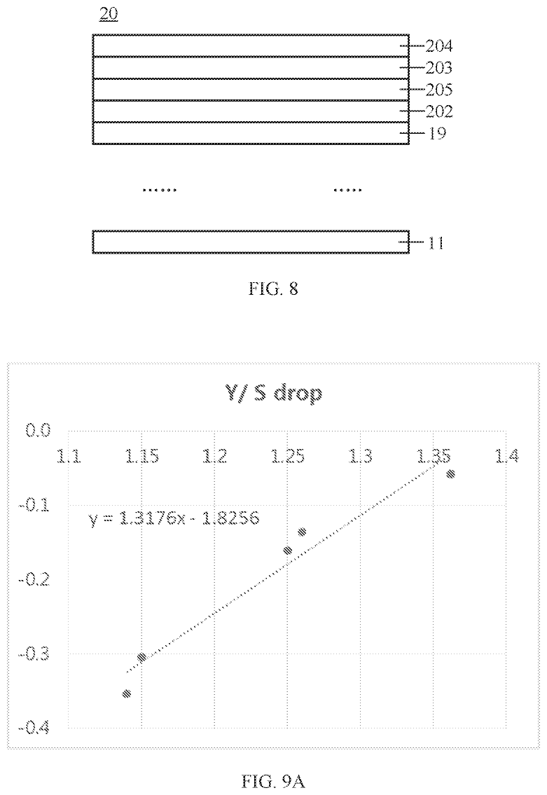

FIG. 8 is a schematic diagram of an encapsulation layer according to another embodiment of the present disclosure.

As shown in FIG. 8, the encapsulation layer 20 may include: the first inorganic layer 202 on the side of the protective layer 19 away from the base substrate 11; a second insertion layer 205 on the side of the first inorganic layer 202 away from the base substrate 11; the organic layer 203 on a side of the second insertion layer 205 away from the base substrate 11; and the second inorganic layer 204 on the side of the organic layer 203 away from the base substrate 11. The sign “ . . . ” in FIG. 8 may represent an omitted film layer structure between the substrate 11 and the protective layer 19.

According to an embodiment of the present disclosure, in the case where the encapsulation layer 20 includes the first inorganic layer 202, the second insertion layer 205, the organic layer 203 and the second inorganic layer 204, the second insertion layer 205 may solely serve as the color shift adjustment layer to reduce the color shift phenomenon of the display substrate. Specifically, a refractive index nₛ₅ of a material of the second insertion layer 205, a thickness Lₛ₅ of the second insertion layer 205, the refractive index nᵢ of a material of one of the remaining film layers, and the thickness Lᵢ of the one of the remaining film layers may have a relationship represented by equation (8):

$${n}_{s 5} {L}_{s 5} + \sum {n}_{i} {L}_{i} / ( {n}_{s 5} + \sum {n}_{i} ) = T . \qquad ( 8 )$$

Here, T is in a range of 65 to 95. A product nₛ₅·Lₛ₅ of the refractive index nₛ₅ of the material of the second insertion layer 205 and the thickness Lₛ₅ of the second insertion layer 205 is in a range of 80 to 160; the refractive index nₛ₅ of the material of the second insertion layer 205 is in a range of 1.5 to 1.7; the refractive index nₛ₅ of the material of the second insertion layer 205 and a refractive index n_{first inorganic layer} of the material of the first inorganic layer meet |nₛ₅-n_{first inorganic layer}|>0.15.

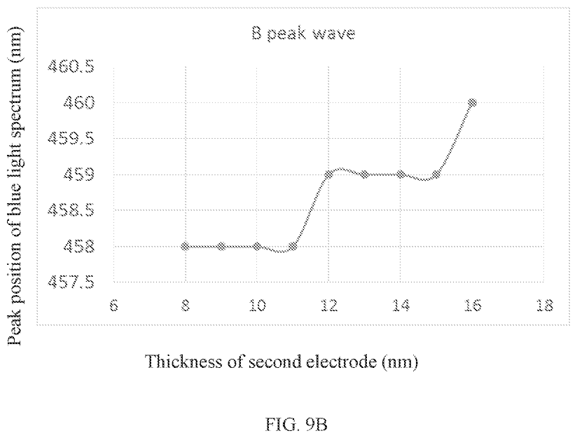

FIG. 9A is a schematic diagram showing a linear relationship of Y-Sdrop in a case of the encapsulation layer shown in FIG. 8 according to an embodiment of the present disclosure.

As shown in FIG. 9A, in the case where the encapsulation layer 20 includes the first inorganic layer 202, the second insertion layer 205, the organic layer 203 and the second inorganic layer 204, and the second insertion layer 205 may solely serve as the color shift adjustment layer, by using the above parameter settings, the effect of the microcavity length variation on Sdrop, i.e. the sensitivity factor of Y-Sdrop, may be 1.32. 1.32 is less than 3.861 in the prior art, and the present disclosure shows significant improvement compared to the prior art, indicating that the display device provided in the embodiments of the present disclosure may effectively reduce the color shift.

Further, the peak of the emitted light is detected in the embodiments of the present disclosure. In the case where the second insertion layer 205 serves as the color shift adjustment layer, the peak position of the spectrum of the first light-emitting sub-layer may be in a range of 620 nm to 635 nm, the peak position of the spectrum of the second light-emitting sub-layer may be in a range of 515 nm to 530 nm, and the peak position of the spectrum of the third light-emitting sub-layer may be in a range of 450 nm to 465 nm.

FIG. 9B is a diagram showing a trend of an effect of a thickness of a second electrode on a blue light spectrum according to an embodiment of the present disclosure.

In the embodiments of the present disclosure, only the relationship between the thickness of the film layer and the refractive index of the film layer may be defined. When the material of the second electrode 17 is preferably Mg/Ag/Al or an alloy, the trend of the effect of the thickness of the second electrode 17 on the RGB light spectrums is as follows. When the thickness of the second electrode 17 is in a range of 8 nm to 16 nm, R_Peak_wave=L+614.56 (L may represent the thickness of the second electrode); G_Peak_wave=0.7x+513 (x may represent the thickness of the second electrode); and B_Peak_wave conforms to the segmentation pattern shown in FIG. 7B. In FIG. 7B, the horizontal coordinate may represent the thickness of the second electrode 17, and the vertical coordinate may represent the variation range of the peak position of the blue light spectrum. When the thickness of the second electrode 17 is in a range of 10 nm to 12 nm and a range of 14 nm to 16 nm, the peak position of the blue light spectrum may show a sudden increasing trend. Here, R_Peak_wave may represent the peak position of the red light spectrum, G_Peak_wave may represent the peak position of the green light spectrum, and B_Peak_wave may represent the peak position of the blue light spectrum.

The embodiments provided in the present disclosure may be applicable to structures such as OLED film layer structures (including film layers in the microcavity being increased or decreased, a plurality of light-emitting stack structures, etc.), multi-layer encapsulation structures, COE devices, EES devices, QLEDs (Quantum Dot Light Emitting Diodes) and white light OLEDs. The differences in film layer materials are only differences with respect to the reference data, but do not affect the fluctuation in the film thickness caused by the same process level, as well as the pattern of the film layer variation.

In the embodiments of the present disclosure, the refractive index and thickness of the color shift adjustment layer are matched, thereby significantly improving the color shift margin sensitivity of the final OLED device structure. By constructing a structure of the film layers that are sensitive to the margin, the sensitivity of RGB to margin changes is reduced, the device performance is improved, the device characteristics are stabilized, and the overall display effect of the device is enhanced.

The embodiments of the present disclosure further provide a display device, which may include the display substrate described in any of the above embodiments. The display device may be any product or component with display function, such as a mobile phone, a tablet, a TV, a monitor, a laptop, a digital photo frame, a navigation device, etc.

It will be understood that the display device provided in the embodiments of the present disclosure includes the above-mentioned display substrate. The beneficial effects of the display device are the same as those of the above-mentioned display substrate, which will not be repeated here.

Although some embodiments of the overall concept of the present disclosure have been illustrated and described, those skilled in the art will understand that changes may be made to these embodiments without departing from the principles and spirit of the overall invention concept of the present disclosure. The scope of the present disclosure is defined by the claims and their equivalents.

1. A display substrate, comprising:
a base substrate;
a first electrode on the base substrate;
a first light-emitting layer on a side of the first electrode away from the base substrate;
a first hole blocking layer on a side of the first light-emitting layer away from the base substrate;
a first electron transport layer on a side of the first hole blocking layer away from the base substrate;
an electron injection layer on a side of the first electron transport layer away from the base substrate;
a second electrode on a side of the electron injection layer away from the base substrate;
an optical extraction layer on a side of the second electrode away from the base substrate;
a protective layer on a side of the optical extraction layer away from the base substrate; and
an encapsulation layer on a side of the protective layer away from the base substrate, the encapsulation layer comprising a plurality of layers,
wherein a refractive index of a material of the optical extraction layer is greater than a refractive index of a material of at least one layer in the encapsulation layer, and the refractive index of the material of the at least one layer in the encapsulation layer is greater than a refractive index of a material of the second electrode.

2. The display substrate according to claim 1, wherein the display substrate comprises a color shift adjustment layer, the color shift adjustment layer is selected from at least one of the group consisting of: the at least one layer in the encapsulation layer, the optical extraction layer, the protective layer or the second electrode, and the color shift adjustment layer, and remaining film layers in the display substrate other than the color shift adjustment layer meet:
$${n}_{s} {L}_{s} + \sum {n}_{i} {L}_{i} / ( {n}_{1} + \sum {n}_{i} ) = T ,$$
wherein nₛ represents a refractive index of a material of the color shift adjustment layer, Lₛ represents a thickness of the color shift adjustment layer, nᵢ represents a refractive index of a material of one of the remaining film layers, and Lᵢ represents a thickness of the one of the remaining film layers;
i is a positive integer, and T is in a range of 45 to 95.

3. The display substrate according to claim 2, wherein the light-emitting layer comprises an R (red) sub-pixel, a G (green) sub-pixel, and a B (blue) sub-pixel, the R sub-pixel is a first light-emitting sub-layer, the G sub-pixel is a second light-emitting sub-layer, and the B sub-pixel is a third light-emitting sub-layer.

4. The display substrate according to claim 3, wherein the encapsulation layer comprises:
a first insertion layer on the side of the protective layer away from the base substrate;
a first inorganic layer on a side of the first insertion layer away from the base substrate;
an organic layer on a side of the first inorganic layer away from the base substrate; and
a second inorganic layer on a side of the organic layer away from the base substrate.

5. The display substrate according to claim 4, wherein a refractive index nₛ₁ of a material of the first insertion layer, a thickness Lₛ₁ of the first insertion layer, the refractive index nᵢ of the material of the one of the remaining film layers, and the thickness Lᵢ of the one of the remaining film layers meet:
$${n}_{s 1} {L}_{s 1} + \sum {n}_{i} {L}_{i} / ( {n}_{s 1} + \sum {n}_{i} ) = T ,$$
wherein T is in a range of 65 to 95.

6. The display substrate according to claim 5, wherein a product nₛ₁·Lₛ₁ of the refractive index nₛ₁ of the material of the first insertion layer and the thickness Lₛ₁ of the first insertion layer is in a range of 70 to 230.

7. The display substrate according to claim 6, wherein the refractive index nₛ₁ of the material of the first insertion layer is in a range of 1.5 to 1.7.

8. The display substrate according to claim 7, wherein the refractive index nₛ₁ of the material of the first insertion layer and a refractive index n_{protective layer} of a material of the protective layer meet |nₛ₁-n_{protective layer}|>0.3.

9. The display substrate according to claim 8, wherein a peak range of the first light-emitting sub-layer is 625 nm to 640 nm, a peak range of the second light-emitting sub-layer is 520 nm to 535 nm, and a peak range of the third light-emitting sub-layer is 455 nm to 465 nm.

10. The display substrate according to claim 3, wherein the encapsulation layer comprises:
a first inorganic layer on the side of the protective layer away from the base substrate;
an organic layer on a side of the first inorganic layer away from the base substrate; and
a second inorganic layer on a side of the organic layer away from the base substrate.

11. The display substrate according to claim 10, wherein a refractive index nₛ₂ of a material of the optical extraction layer, a thickness Lₛ₂ of the optical extraction layer, the refractive index nᵢ of the material of the one of the remaining film layers, and the thickness Lᵢ of the one of the remaining film layers meet:
$${n}_{s 2} {L}_{s 2} + \sum {n}_{i} {L}_{i} / ( {n}_{s 2} + \sum {n}_{i} ) = T ,$$
wherein T is in a range of 45 to 55.

12. The display substrate according to claim 11, wherein a product nₛ₂·Lₛ₂ of the refractive index nₛ₂ of the material of the optical extraction layer and the thickness Lₛ₂ of the optical extraction layer is in a range of 90 to 150,
wherein the refractive index ns2 of the material of the optical extraction layer is in a range of 1.8 to 2.2;
wherein the refractive index ns2 of the material of the optical extraction layer and a refractive index nprotective layer of a material of the protective layer meet |ns2-nprotective layer|>0.5; and
wherein a peak range of the first light-emitting sub-layer is 633 nm to 654 nm, a peak range of the second light-emitting sub-layer is 515 nm to 530 nm, and a peak range of the third light-emitting sub-layer is 455 nm to 465 nm.

13-15. (canceled)

16. The display substrate according to claim 10, wherein a refractive index nₛ₃ of a material of the protective layer, a thickness Lₛ₃ of the protective layer, the refractive index nᵢ of the material of the one of the remaining film layers, and the thickness Lᵢ of the one of the remaining film layers meet:
$${n}_{s 3} {L}_{s 3} + \sum {n}_{i} {L}_{i} / ( {n}_{s 3} + \sum {n}_{i} ) = T ,$$
wherein T is in a range of 55 to 65.

17. The display substrate according to claim 16, wherein a product nₛ₃·Lₛ₃ of the refractive index nₛ₃ of the material of the protective layer and the thickness Lₛ₃ of the protective layer is in a range of 50 to 110;
wherein the refractive index ns3 of the material of the protective layer is in a range of 1.3 to 1.5;
wherein the refractive index ns3 of the material of the protective layer and a refractive index noptical extraction layer of the material of the optical extraction layer meet |ns3-noptical extraction layer|>0.5; and
wherein a peak range of the first light-emitting sub-layer is 615 nm to 630 nm, a peak range of the second light-emitting sub-layer is 515 nm to 530 nm, and a peak range of the third light-emitting sub-layer is 450 nm to 465 nm.

18-20. (canceled)

21. The display substrate according to claim 10, wherein a refractive index nₛ₄ of a material of the second electrode, a thickness Lₛ₄ of the second electrode, the refractive index nᵢ of the material of the one of the remaining film layers, and the thickness Lᵢ of the one of the remaining film layers meet:
$${n}_{s 4} {L}_{s 4} + \sum {n}_{i} {L}_{i} / ( {n}_{s 4} + \sum {n}_{i} ) = T ,$$
wherein T is in a range of 60 to 65.

22. The display substrate according to claim 21, wherein a product nₛ₄·Lₛ₄ of the refractive index nₛ₄ of the material of the second electrode and the thickness Lₛ₄ of the second electrode is in a range of 1.5 to 2.0;
wherein the refractive index ns4 of the material of the second electrode is in a range of 0.1 to 0.2;
wherein the refractive index ns4 of the material of the second electrode and a refractive index noptical extraction layer of a material of the optical extraction layer meet |ns4-noptical extraction layer|>1; and
wherein a peak range of the first light-emitting sub-layer is 615 nm to 625 nm, a peak range of the second light-emitting sub-layer is 520 nm to 530 nm, and a peak range of the third light-emitting sub-layer is 455 nm to 465 nm.

23-25. (canceled)

26. The display substrate according to claim 3, wherein the encapsulation layer comprises:
a first inorganic layer on the side of the protective layer away from the base substrate;
a second insertion layer on a side of the first inorganic layer away from the base substrate;
an organic layer on a side of the second insertion layer away from the base substrate; and
a second inorganic layer on a side of the organic layer away from the base substrate.

27. The display substrate according to claim 26, wherein a refractive index nₛ₅ of a material of the second insertion layer, a thickness Lₛ₅ of the second insertion layer, the refractive index nᵢ of the material of the one of the remaining film layers, and the thickness Lᵢ of the one of the remaining film layers meet:
$${n}_{s 5} {L}_{s 5} + \sum {n}_{i} {L}_{i} / ( {n}_{s 5} + \sum {n}_{i} ) = T ,$$
wherein T is in a range of 65 to 95;
wherein a product ns5·Ls5 of the refractive index ns5 of the material of the second insertion layer and the thickness Ls5 of the second insertion layer is in a range of 80 to 160;
wherein the refractive index ns5 of the material of the second insertion layer is in a range of 1.5 to 1.7;
wherein the refractive index ns5 of the material of the second insertion layer and a refractive index nfirst inorganic layer of a material of the first inorganic layer meet |ns5-nfirst inorganic layer|>0.15; and
wherein a peak range of the first light-emitting sub-layer is 620 nm to 635 nm, a peak range of the second light-emitting sub-layer is 515 nm to 530 nm, and a peak range of the third light-emitting sub-layer is 450 nm to 465 nm.

28-31. (canceled)

32. The display substrate according to claim 1, further comprising:
a hole injection layer on the side of the first electrode away from the base substrate;
a first hole transport layer on a side of the hole injection layer away from the base substrate;
a second light-emitting layer on a side of the first hole transport layer away from the base substrate;
a second hole blocking layer on a side of the second light-emitting layer away from the base substrate;
a second electron transport layer on a side of the second hole blocking layer away from the base substrate;
a charge generation layer on a side of the second electron transport layer away from the base substrate; and
a second hole transport layer on a side of the charge generation layer away from the base substrate, wherein the first light-emitting layer is on a side of the second hole transport layer away from the base substrate;
wherein a material of the first electrode comprises at least one of silver, indium tin oxide/silver/indium tin oxide, or a nickel chromium alloy;
wherein the material of the second electrode comprises at least one of a transparent conductive oxide, a magnesium silver alloy, aluminum, magnesium, or silver;
wherein Sdrop ≤0, and Sdrop is obtained through a following equation:
Sdrop=((Ssplit−Sref·)/Sref·)*100%, and
wherein Ssplit is an area of an enclosed color gamut of the display substrate in a color space, Sref, is an area of an enclosed color gamut of a reference display substrate in the color space, and Sdrop is a variation in split S with respect to Sref.

33-34. (canceled)

35. A display device comprising the display substrate according to claim 1.
